(19) United States
(12) Patent Application Publication
(10) Pub. No.: US 2015/0275365 A1
(43) Pub. Date: Oct. 1, 2015

(54) Atomic Layer Deposition Using Injector Module Arrays

(71) Applicant: Veeco ALD Inc., Fremont, CA (US)

(72) Inventors: Samuel S. Pak, San Ramon, CA (US); Sang In Lee, Los Altos Hills, CA (US)

(21) Appl. No.: 14/664,700

(22) Filed: Mar. 20, 2015

Related U.S. Application Data
(60) Provisional application No. 61/971,427, filed on Mar. 27, 2014.

(51) Int. Cl. C23C 16/455; C23C 16/458

(52) U.S. Cl. CPC C23C 16/45551; C23C 16/4584; C23C 16/45525

(57) ABSTRACT

An atomic layer deposition (ALD) device includes an array of a plurality of injector modules configured in a plane parallel to a substrate. The plurality of injector modules that form the array are, in some embodiments, configured in a regular array such as in a matrix of columns and/or rows of injector modules. In other embodiments of the array, the injector modules are configured in a periodic pattern. Each of the injector modules of the array injects both source precursor and reactant precursor onto the substrate.

### CROSS REFERENCE TO RELATED APPLICATIONS

This application claims priority to and the benefit of U.S. Provisional Application No. 61/971,427, filed Mar. 27, 2014, which is incorporated by reference in its entirety.

### BACKGROUND

1. Field of Art

The disclosure relates to forming a layer of material on a substrate using atomic layer deposition (ALD).

2. Description of the Related Art

Atomic layer deposition (ALD) is one way of depositing material on a substrate. ALD uses the bonding force of a chemisorbed molecule that is different from the bonding force of a physisorbed molecule. In ALD, source precursor is adsorbed onto the surface of a substrate and then purged with an inert gas. As a result, physisorbed molecules of the source precursor (bonded by the Van der Waals force) are desorbed from the substrate. However, chemisorbed molecules of the source precursor are covalently bonded, and hence these molecules are strongly adsorbed on the substrate and not desorbed from the substrate during purging or evacuating. The chemisorbed molecules of the source precursor (adsorbed on the substrate) react with and/or are replaced by molecules of reactant precursor. Then, the excessive precursor or physisorbed molecules are removed by injecting the purge gas and/or pumping the chamber, producing a final atomic layer.

### SUMMARY

Embodiments relate to performing atomic layer deposition (ALD) on a substrate using an array of injector modules having injection portions facing the substrate and placed in a plane parallel to the surface of the substrate onto which an ALD layer is deposited. The plurality of injector modules that form the array are, in some embodiments, configured in a regular array such as in a matrix of columns and/or rows of injector modules. Each injector module of the array is configured so that a corresponding precursor output portion of each module confronts a substrate and is separated from the substrate by a predetermined distance.

Each of the injector modules of the array injects both source precursor and reactant precursor onto the substrate. Injecting both source precursor and reactant precursor using the same injector module reduces the displacement of a substrate needed to deposit a layer of material. In order to deposit the layer on a portion of the substrate, the portion is exposed to both the source precursor and the reactant precursor. Because each injector module of the array provides both reactant and source precursors simultaneously, the relative displacement between the substrate and the injector modules can be small.

### BRIEF DESCRIPTION OF DRAWINGS

FIG. 1A is a cross sectional diagram of a linear deposition device for performing atomic layer deposition, according to an embodiment.

FIG. 1B is a perspective view of a linear deposition device, according to one embodiment.

FIG. 2A is a perspective view of an array of injection modules, according to one embodiment.

FIG. 2B is a bottom view of the array deposition device shown in FIG. 2A, according to one embodiment.

FIG. 3A is a cross sectional diagram of a deposition device for performing atomic layer deposition, according to one embodiment.

FIG. 3B is a bottom view of an array deposition device that includes an illustration of relative movement of a substrate and the array of injection modules according to a first movement profile and a second concurrent movement profile, according to one embodiment.

FIG. 3C is a bottom view of an array deposition device that includes an illustration of relative movement of a substrate and an array of injection modules according to a first movement profile and a second concurrent movement profile, according to another embodiment.

FIG. 4 is an elevational view of an injection module and a corresponding conduit, according to one embodiment.

FIG. 5A is a cross sectional diagram of the injection module of FIG. 4 taken along plane A-B of FIG. 4, according to one embodiment.

FIG. 5B is a cross sectional diagram of the injection module taken along line C-D of FIG. 5A, according to one embodiment.

FIG. 6 is a cross sectional diagram of an injection module, according to another embodiment.

FIG. 7 is a flow chart for a method of performing atomic layer deposition, according to an embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to performing atomic layer deposition (ALD) on a substrate using an array of injector modules having injection portions facing the substrate placed in a plane parallel to the surface of the substrate onto which an ALD layer is deposited. The plurality of injector modules that form the array are, in some embodiments, configured in a regular array such as in a matrix of columns and/or rows of injector modules. In other embodiments of the array, the injector modules are configured in a periodic pattern. Each injector module of the array is configured so that a corresponding precursor output portion of each module is disposed in a plane facing and parallel to a surface of a substrate and is separated from the substrate by a predetermined distance.

Each of the injector modules of the array injects both source precursor and reactant precursor onto the substrate. Injecting both source precursor and reactant precursor using the same injector modules reduces the displacement of a substrate needed to deposit a layer of material. To deposit the layer on a portion of the substrate, the portion is exposed to both the source precursor and the reactant precursor. Because each injector module of the array provides both reactant and source precursors simultaneously, the relative displacement between the substrate and the injector modules used to deposit a layer of material can be small. That is, to deposit a layer of material the relative displacement distance in a width direction of the substrate may be shorter than the width Ω of the substrate and the relative displacement distance in a length direction of the substrate may be shorter than the length of the substrate.

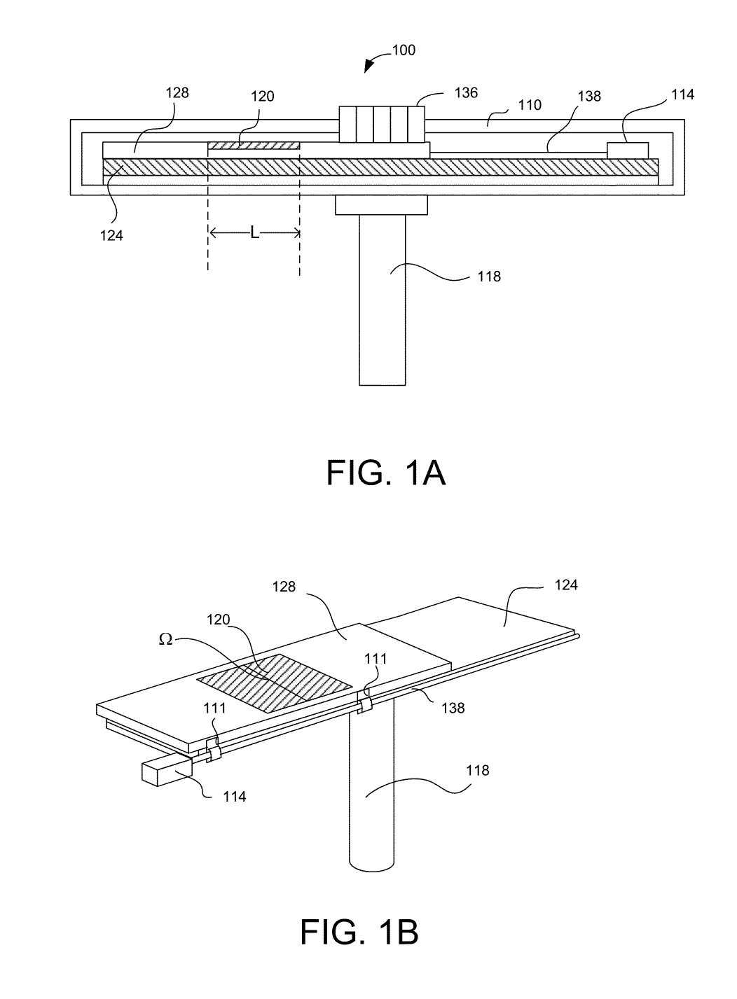

FIG. 1A is a cross sectional diagram of a linear deposition device 100 for performing an ALD process, according to one embodiment. FIG. 1B is a perspective view of the linear deposition device 100 (without chamber walls to facilitate explanation), according to one embodiment. The linear deposition device 100 may include, among other components, a support pillar 118, the process chamber 110 and one or more reactors 136. The reactors 136 may include one or more of injectors and radical reactors. Each of the injectors injects purge gas, metal containing precursor or organic precursor onto the substrate 120.

The process chamber enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement.

The susceptor 128 may be secured to brackets 111 that move across an extended bar 138 with screws formed thereon. The brackets 111 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 111 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128.

When using such linear deposition device 100, a minimum stroke distance for performing the ALD on the entire susceptor 128 is 3L where L represents the length of the substrate 120 as illustrated in FIG. 1A. If the length of the substrate 120 large, the stroke distance can be quite large. The increased stroke distance results in a larger linear deposition device 100, which occupies a larger space.

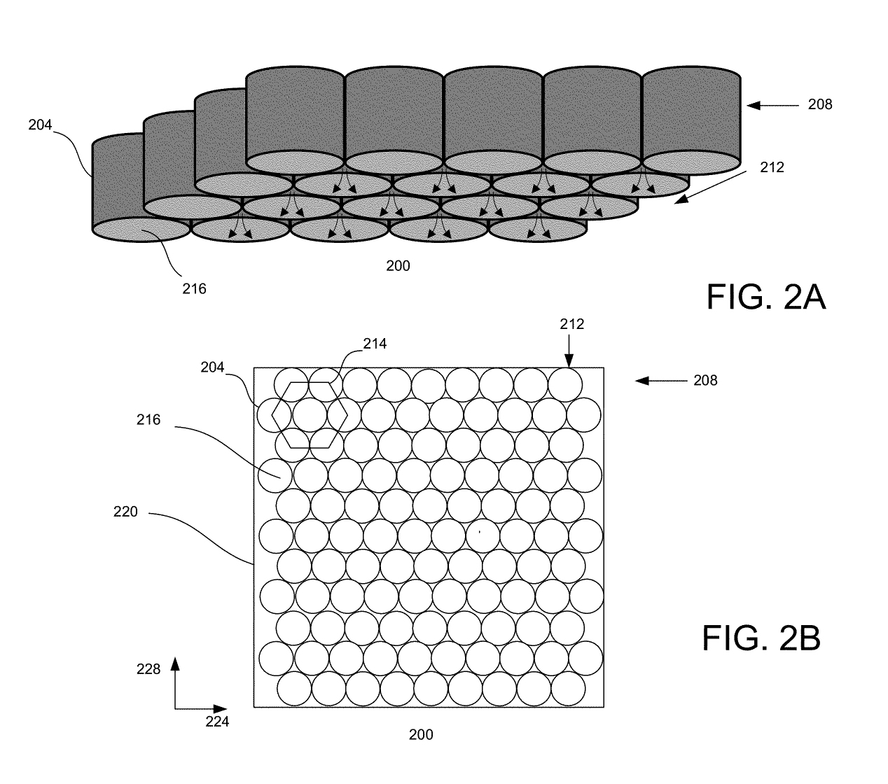

FIG. 2A is a perspective view of an array 200 of injection modules 204, according to one embodiment. In this embodiment, the array 200 shown is as rows 208 and columns 212, the individual injectors of which are arranged in a body-centered hexagonal pattern (referred to herein as a “hexagonal-grid array,” a unit cell of which is indicated by hexagon 214 in FIG. 2B). Alternatively, this hexagonal-grid array can be viewed as a rhombus-grid array. The hexagonal-grid array embodiment is shown only for convenience. Other configurations of injection modules may be configured into a two-dimensional array without departing from the present disclosure. That is, in other configurations the individual injection modules of the array are not merely arranged linearly (and serially) in a single row as shown in FIG. 2A, but rather are distributed over a plane defined by two dimensions in any pattern. In other words, the individual modules of the array are not configured in a single direction but rather are configured over an area defined by a first direction and a second direction. Examples include a square-grid array, a rectangular-grid array, and other periodic and non-periodic two dimensional configurations.

As shown by arrows in FIG. 2A, inert gas may be injected towards a substrate (not shown) via gaps between the injection modules 204 to prevent back-diffusion of source precursor and reactant precursor. The inert gas injected via the gaps into a clearance space between the injection modules and a substrate may also function as a gas bearing mechanism that prevents contact between the substrate and a precursor injection (bottom) portion 216 of the injection modules. The precursor output portion 216 shown generically in FIG. 2A refers to a part of each injection module 204 that confronts a substrate (not shown) and from which one or both of reactant precursor and source precursor issues to deposit on the substrate.

FIG. 2B is a bottom view of the array 200 shown in FIG. 2A and illustrates the planar configuration of the array. As in FIG. 2A, FIG. 2B omits a depiction of a susceptor for clarity of explanation. The injection module array 200 includes a plurality of injection modules 204 arranged in the rows 208 and the columns 212 that are also shown in the perspective view of FIG. 2A. Although not illustrated in FIG. 2B, the injection module array 200 may include frames and securing means (e.g., bolts or screws) to secure the injection modules 204. For further illustration and clarity of explanation, a plane 220 in which the precursor output surfaces 216 of the plurality of injection modules of the array 200 are arranged is shown. The plane 220 is defined by identifying two directions in which the plane extends, in this case a first direction 224, in a width direction of a substrate, and a second direction 228, in a length direction of the substrate. While these two directions are orthogonal and roughly correspond to the directions of rows 208 and columns 212, the directions defining the plane 220 need not be orthogonal.

As described above, an array of injection modules 204, whether arranged as shown in FIGS. 2A and 2B or arranged in another configuration, provides numerous processing benefits. First, because all of the injection modules 204 provide both reactant precursor and source precursor to a substrate, the displacement of a substrate to deposit a final layer of material need not exceed the length L of substrate or the width Ω of the substrate, as described above. This is because a substrate need not be exposed to each injector module in a linear series to provide both source precursor and reactant precursor.

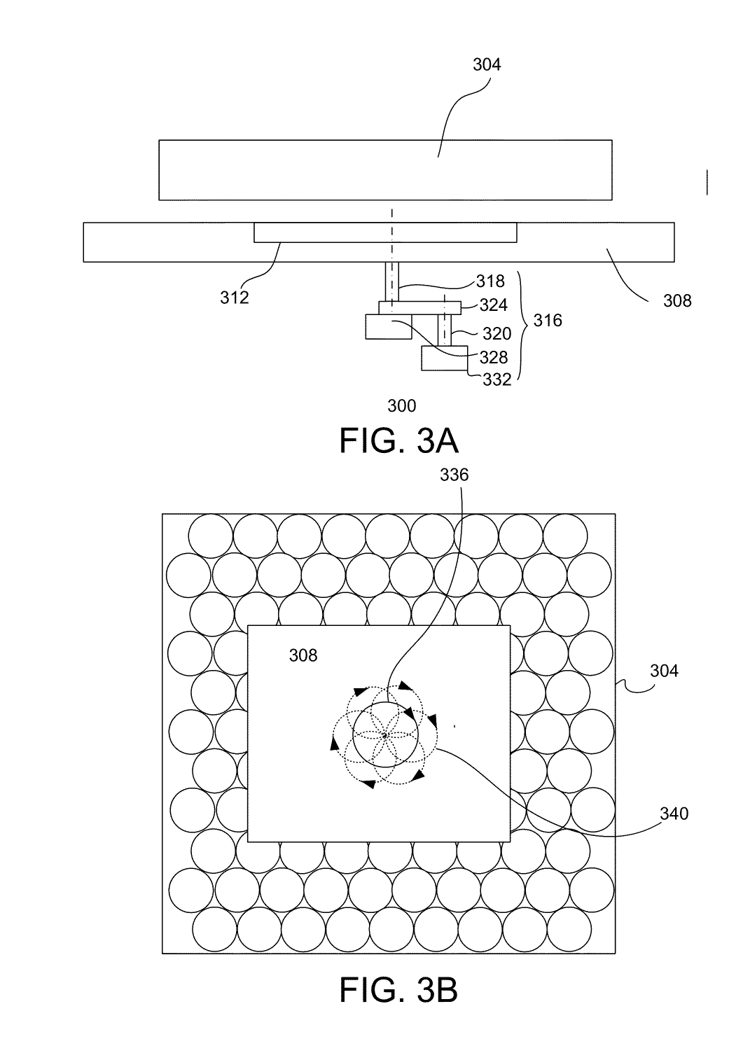

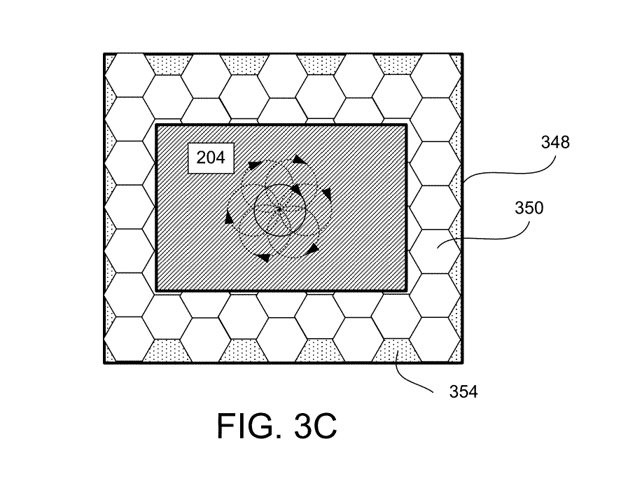

One embodiment of using an injection module array 200 and non-linear motion profiles is schematically illustrated in FIGS. 3A and 3B. FIG. 3A illustrates an array deposition device having a double-planetary displacement system for moving a susceptor and corresponding substrate. FIG. 3B illustrates the double-planetary motion of the susceptor and corresponding substrate in the context of the plan view of the array 200.

The array deposition device 300 of FIG. 3A includes an injection module array 304, a susceptor 308 on which is disposed a substrate 312, and a moving mechanism 316. The moving mechanism 316 causes a relative movement between the injection module array 304 and the susceptor 308 so that parts of the substrate 312 are injected with different gases by the injection modules in the injection module array 304.

For array deposition devices, such as device 300, it is possible to use a combination of a first motion profile and a second motion profile so that portions of the substrate 312 pass below more injection modules of the array 304, thereby increasing a deposition rate of a corresponding layer. Conventionally, the moving mechanism 316 would translate the susceptor and attached substrate linearly to correspond to the single row of linearly arranged injection modules. However, for injection modules configured as an array, as disclosed herein, the moving mechanism 316 is not limited to linear translation because the injection modules are arranged in a two-dimensional array, and not a single “one dimensional” row. As such, the example moving mechanism 316 is configured for double planetary movement and includes shafts 318, 320, a cam plate 324 connected to the shafts 314, 320, and two motors 328, 332 for rotating the shafts 318, 320.

In one embodiment, the moving mechanism 316 causes the susceptor 308 (and the substrate 312) to move in directions indicated by circles 336, 340. The circle 336 shown by a solid line represents a primary motion profile of shaft 320 and the circles 340 shown by dashed lines represent a secondary motion profile of shaft 318. Each complete rotational movement of the shaft 318 corresponds to ⅙ of the entire circular movement of shaft 320. Each of the circles 340 corresponds to an additional ⅙ of the entire circular movement of the shaft 318. In this way, the susceptor 308 makes repeated “rotations,” each having a first radius, during the performance of a single “revolution,” which has a second radius.

In other embodiments, different movement motions such as repeated straight linear movement, elliptic movement or irregular movement of the susceptor 308 may be used.

In other embodiments, the susceptor may move along a different motion profile. For example, the susceptor may move along only the primary motion profile without movement along the secondary motion profile. Further, the susceptor may move along in a reciprocal linear motion profile instead of circular or elliptic motion profile.

FIG. 3C is a bottom view of an array deposition device 348, according to another embodiment. In this example, each of injection modules 350 is a column having a hexagonal cross section so that the array deposition device 350 has a honeycomb structure. By having the honeycomb cross-section, the injection modules 350 can be adjoined without gaps between the injection modules 350. Further, inert gas may also be injected via areas 354 of the array deposition device to prevent back-diffusion of the source precursor and the reactant precursor injected by the injection modules 350.

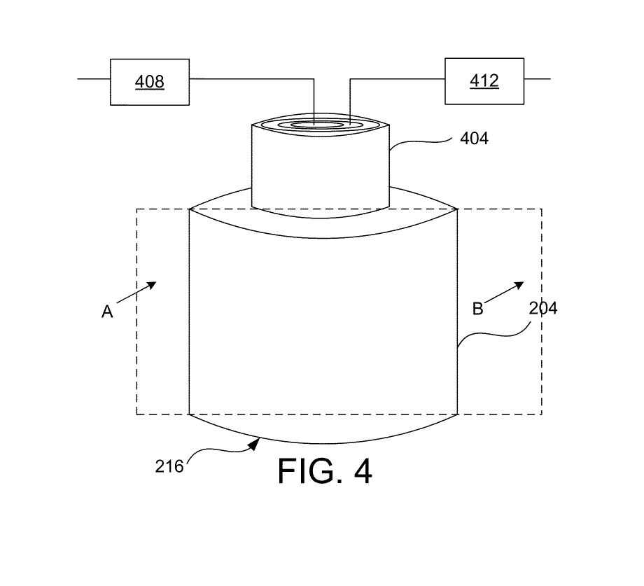

Each injector array, regardless of the specific two-dimensional array configuration, includes a plurality of injection modules that provide both source precursor and reactant precursor to a substrate. FIG. 4 is one example of such an injector module. FIG. 4 is a perspective view of an injection module 204 in the array 200, according to one embodiment. The injection module 204 includes a conduit 404 for providing gas to the injection module 204, according to one embodiment. The injection module 204 has a cylindrical shape and is formed with chambers and channels for routing gases for injection to a substrate and discharging excess gases from the substrate. As described above, the precursor output portion 216 is disposed in a plane parallel to a surface of the substrate and is separated from the substrate by a predetermined height to preferably prevent contact between the injection module 204 and the substrate.

The conduit 404 is connected to sources of various gases via valves 408, 412. The valves 408, 412 can be switched on or off to selectively connect the conduit 404 to the sources of the gases.

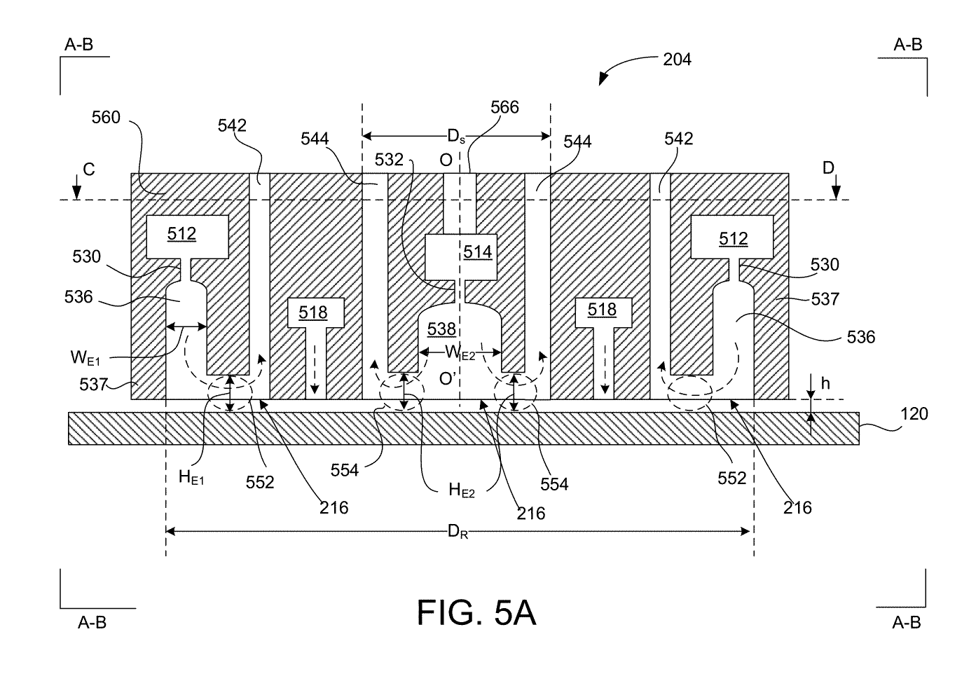

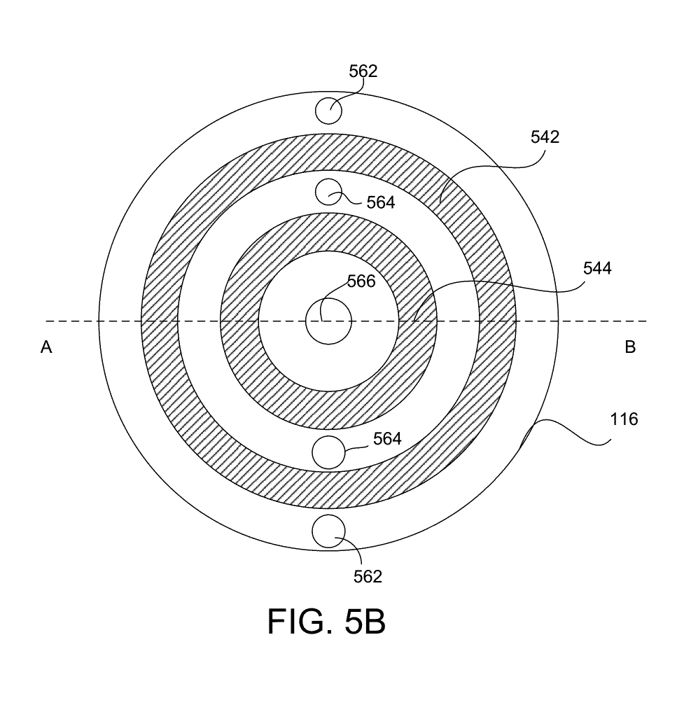

FIG. 5A is a cross sectional diagram of the injection module 204 taken along plane A-B of FIG. 4, according to one embodiment. The bottom of the body 560 is separated from the top surface of the substrate 120 by a distance of h. The body 560 of the injection module 204 is formed with channels 512, 514, 518 to convey gases to the precursor output portion 216. In some embodiments, the various channels 512, 514, 518, and the exhausts 542 and 544 are concentric with one another, as shown in the figures.

The channel 512 is formed in the outer periphery of the body 560 at a first distance from a center of the body, as measured from O-O′. In one embodiment, the channel 512 carries reactant precursor gas received via the conduit 404. The reactant precursor travels via perforations or slit 530 to an injection chamber 536 having a width of W_{E1}. The substrate 120 is injected with the reactant precursor below the injection chamber 536. As a result, the source precursor may react or replace source precursor adsorbed on the substrate 120 and form a layer of material on the substrate 120.

The reactant precursor moves through a constriction zone 552 and is discharged via an exhaust 542. The exhaust 542 is at a third distance from the center of the body that is less than the first distance but greater than the distances from the center corresponding to separation gas channel 518, exhaust 544, and the channel 514, as described below. The constriction zone 552 has a height H_{E1} that is smaller than the width W_{E1} of the injection chamber 536. In one embodiment, the height H_{E1} is from 1 mm to 4 mm. Due to the reduced size of passage in the constriction zone 552, the speed of the reactant precursor in the constriction zone 552 is increased while the pressure of the reactant precursor is decreased in the constriction zone 552 compared to the reactant precursor in the injection chamber 536. Thus, the reactant precursor facilitates the removal of excess reactant precursor (e.g., reactant precursor molecules physisorbed on the substrate 120) while leaving the deposited material intact on the substrate 120.

To cause sufficient Bernoulli effect in the constriction zone 552, the height H_{E1} of the constriction zone 552 is smaller than ⅔ of the width W_{E1}, and more preferably smaller than ⅓ of the diameter W_{E1}. The constriction zone 552 also enables the reactant precursor to form self-sustaining laminar flow to cause the reactant precursor to react or replace the source precursor in a uniform manner. The constriction zone 552 reduces leaking or diffusion of reactant precursor beyond outer wall 537 of the injection module 204 by facilitating discharge of the reactant precursor through the exhaust 542 due to pressure at the constriction zone 552 that is lower than the pressure gap (with height of h) between the outer wall 537 and the substrate 120. Whenever the injection module 204 is moving relative to the substrate 120, the molecules of the reactant precursor are adsorbed on the substrate 120 across an area having an outer diameter of D_{R}.

The channel 514 is formed at a second distance less than the first distance that is near center axis O-O′ of the injection module 204. In one embodiment, the channel 514 carries source precursor. The source precursor in the channel 514 is injected into an injection chamber 538 via a perforation 532. The injection chamber 538 has a diameter of W_{E2}. The portion of the substrate 120 below the injection chamber 538 is injected with the source precursor. Part of the injected source precursor is adsorbed on the substrate 120 while remaining excess source precursor is discharged via the constriction zone 554 to an exhaust 544. The constriction zone 554 has a height H_{E2} that is smaller than the diameter W_{E2} of the injection chamber 538. The exhaust 544 is at a fourth distance that is between the fifth distance (corresponding to the separation gas channel 518 described below) and the second distance (corresponding to channel 514).

As a result, the pressure of the source precursor drops and the speed of the source precursor increases as the source precursor passes through the constriction zone 554, facilitating removal of excess source precursor (e.g., source precursor molecules physisorbed on the substrate 120) while leaving source precursor molecules chemisorbed on the substrate 120 intact.

To cause sufficient Bernoulli effect in the constriction zone 554, the height H_{E2} of the constriction zone 554 is smaller than ⅔ of the diameter W_{E2}, and more preferably smaller than ⅓ of the diameter W_{E2}. The constriction zone 554 also enables the source precursor to form self-sustaining laminar flow to adsorb the source precursor in a uniform manner. When the injection module 204 moves relative to the substrate 120, an area with diameter Ds is exposed to the source precursor.

The channel 518 carries separation gas (e.g., inert gas such as Argon). The separation gas forms an air curtain between the portion of the injection module 204 injecting the source precursor and the portion of the injection module 204 injecting the reactant precursor. In this way, the mixing of the source precursor and the reactant precursor is prevented from occurring at places other than on the substrate 120. Hence, formation of particles due to the reaction between source precursor and the reactant precursor can be prevented. The channel 518 is disposed at a fifth distance from the center of the body between the third distance (corresponding to exhaust 542) and the fourth distance (corresponding to exhaust 544).

As the injection module 204 moves over the substrate 120, the portion of the substrate 120 previously exposed to the source precursor is subsequently exposed to the reactant precursor. That is, the area represented by diameter Ds is exposed to the source precursor and then the reactant precursor. As a result of the reaction between the source precursor and the reactant precursor, a layer of material is deposited on the substrate 120 that is an intersection of areas defined by diameters D_{R} and D_{S} as the substrate and injection modules of the array move relative to one another.

In one embodiment, the distance h is either a function of diameter Ds or may be set to a fixed value, for example, in the range of 0.1 mm to 3 mm. For example, the distance h is set to a value less than one tenth of D_{S} to minimize the precursor leak through this gap.

FIG. 5B is a cross sectional diagram of the injection module 204 taken along line C-D of FIG. 5A, according to one embodiment. The injection module 204 is formed with inlets 562 for receiving the reactant precursor, inlets 564 for receiving the separation gas, and an inlet 566 for receiving the source precursor. The reactant precursor, the separation gas and the source precursor are transferred to the channel 512, the channel 518 and the channel 514 (as shown in FIG. 5A), respectively, via holes (not shown) formed in the body 560.

The body 560 of the injection module 204 is also formed with exhausts 542, 544 for discharging the excess reactant precursor and the excess source precursor, respectively. The exhausts 542, 544 are connected to the injection chambers 536, 538 via constriction zones 552 and 554.

Although the injection module 204 of FIGS. 5A and 5B is illustrated as being symmetric with respect to the axis O-O′, other embodiments may have non-symmetric shape or configuration.

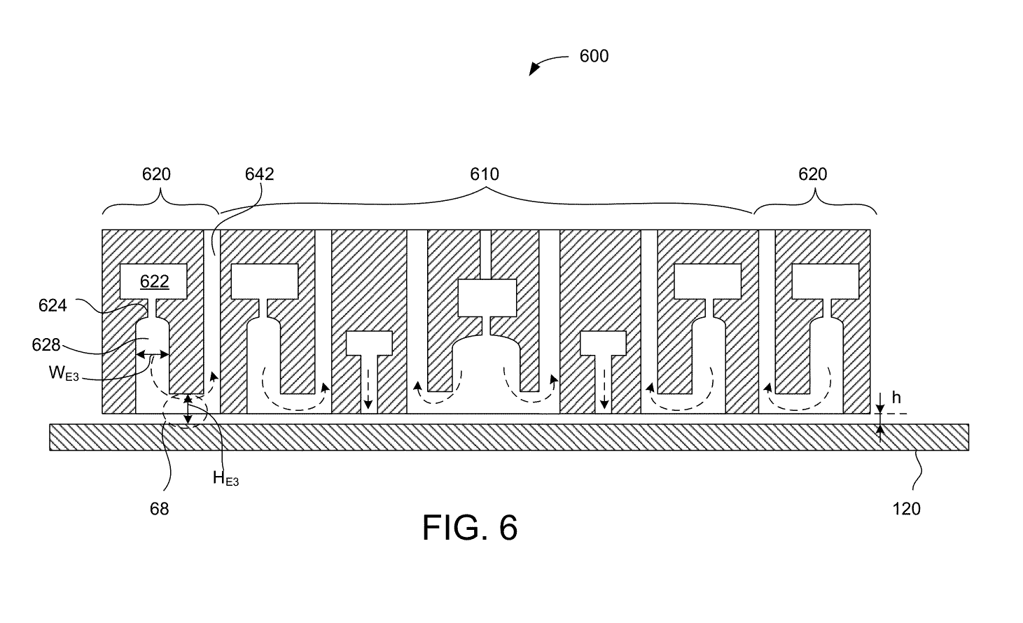

FIG. 6 is a sectional diagram of an injection module 600, according to another embodiment. The injection module 600 includes a first portion 610 and a second portion 620. The first portion 610 is identical to the injection module 204 of FIGS. 5A and 5B, and therefore, detailed description thereof is omitted herein for the sake of brevity. The injection module 600 further includes the second portion 620 for injecting purge gas (e.g., inert gas) through channel 622, perforations or slits 624, and an injection chamber 628. The gas in the injection chamber 628 is injected onto the substrate 120 to remove excess reactant precursor or other excess material from the surface of the substrate 120. In order to enhance the removal process, a constriction zone 638 having the height H_{E3} smaller than the width W_{E3} is formed in the injection module 600. As the purge gas moves through the constriction zone 638, the pressure of the purge gas drops and the speed of the purge gas increases due to Bernoulli effect. The purge gas and any excess material are discharged via exhaust 642.

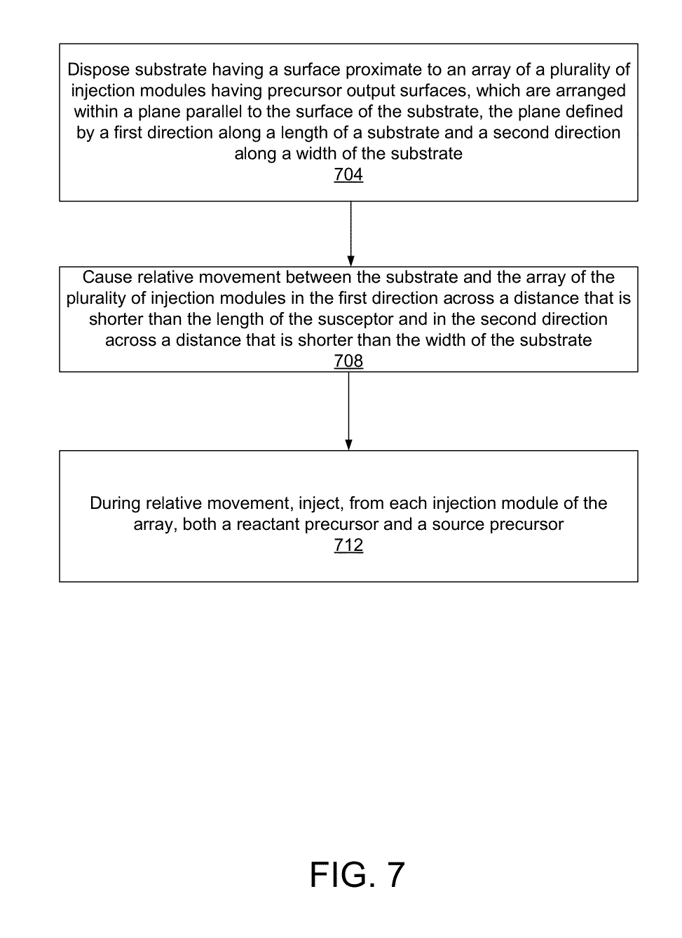

FIG. 7 is a flow chart for a method of performing atomic layer deposition, according to an embodiment. In this embodiment, a substrate is disposed 704 proximate to an array of a plurality of injection modules having precursor output surfaces. The precursor output surfaces are arranged within a plane parallel to the surface of the substrate. The plane is defined by a first direction along a length of a substrate and a second direction along a width of the substrate. Relative movement is caused 708 between the substrate and the array of the plurality of injection modules in the first direction across a distance that is shorter than the length of the susceptor and in the second direction across a distance that is shorter than the width of the substrate. During the relative movement, each injection module of the array injects 712 both a reactant precursor and a source precursor onto the surface of the substrate.

What is claimed is:

1. A deposition device comprising:
an injection module array comprising at least two rows of injection modules, each row including at least two adjacent injection modules, each of the at least two injection modules comprising a precursor output surface and a body, the precursor output surface facing a surface of a substrate arranged within a plane parallel to the surface of the substrate, the plane defined by a first direction along a length of the substrate and a second direction along a width of the substrate, the body formed with:
a first channel disposed at a first distance from a center of the body and configured to carry one of reactant precursor and source precursor to the precursor output surface, and
a second channel disposed at a second distance from the center of the body and configured to carry the other of reactant precursor and source precursor to the precursor output surface;
a susceptor configured to secure the substrate to face precursor output surfaces of the at least two rows of injection modules; and
an actuator configured for cause a relative movement between the array and the susceptor in the first direction across a distance that is shorter than the length of the susceptor and in the second direction across a distance that is shorter than the width of the substrate.

2. The deposition device of claim 1, wherein the body of each injection module further defines at the precursor output surface both of a source precursor injection chamber and a reactant precursor injection chamber.

3. A deposition device comprising:
an array of a plurality of injection modules, the array having precursor output surfaces facing a surface of a substrate and arranged within a plane parallel to the surface of the substrate, the plane defined by a first direction along a length of the substrate and a second direction along a width of the substrate;
a susceptor configured to secure the substrate to face the precursor output surfaces of the plurality of injection modules; and
an actuator configured to cause a relative movement between the array and the susceptor in the first direction across a distance that is shorter than the length of the susceptor and in the second direction across a distance that is shorter than the width of the substrate.

4. The deposition device of claim 3, wherein each of the plurality of injection modules comprises a body formed with:
a first channel disposed at a first distance from a center of the body and configured to carry one of reactant precursor and source precursor; and
a second channel disposed at a second distance from the center of the body less than the first distance, the second channel configured to carry at least the other of reactant precursor and source precursor.

5. The deposition device of claim 4 wherein the first channel is concentric with the second channel.

6. The deposition device of claim 5, wherein:
the first channel is in communication with a first injection chamber, the first injection chamber at the first distance from the center of the body, the first injection chamber in communication with a first exhaust, the first exhaust disposed at a third distance from the center of the body, the third distance between the first distance and the second distance; and
the second channel is in communication with a second injection chamber, the second injection chamber at the second distance from the center of the body, the second injection chamber in communication a second exhaust at a fourth distance from the center of the body, the fourth distance between second distance and the third distance.

7. The deposition device of claim 5, further comprising a separation gas channel disposed between the first exhaust of the first channel and one of the second exhausts, the second separation gas channel disposed at a fifth distance from the center of the body, the fifth distance between the third distance and the fourth distance.

8. The deposition device of claim 4, wherein the body of each of the injection modules has a hexagonal cross-section.

9. The deposition device of claim 4, wherein the body of each injection module has a circular cross-section.

10. The method of claim 3, wherein the relative movement is concurrent motion according to a first motion profile and a second motion profile.

11. The method of claim 10, wherein the first motion profile is a rotation and the second motion profile is a revolution.

12. The method of claim 3, wherein the deposition device is an atomic layer deposition (ALD) device.

13. An atomic layer deposition method comprising:
disposing a substrate having a surface proximate to an array of a plurality of injection modules, each injection module of the plurality having precursor output surfaces, the precursor output surfaces arranged within a plane parallel to the surface of the substrate, the plane defined by a first direction along a length of the substrate and a second direction along a width of the substrate;
causing a relative movement between the substrate and the array of the plurality of injection modules in the first direction across a distance that is shorter than the length of the susceptor and in the second direction across a distance that is shorter than the width of the substrate; and
during the relative movement, injecting, from each injection module of the array, both a reactant precursor and a source precursor onto a surface of the substrate.

14. The method of claim 13, wherein the relative movement is concurrent motion according to a first motion profile and a second motion profile.

15. The method of claim 14, wherein the first motion profile is a rotation and the second motion profile is a revolution.

16. The method of claim 13, further comprising injecting inert gas through a plurality of gaps disposed between adjacent injection modules of the plural injection modules.

17. The method of claim 13, wherein the injection of both the reactant precursor and the source precursor from each injection module further comprises:
exposing a portion of the surface of the substrate to source precursor from an injection module; and
responsive to the relative movement, exposing the portion of the surface of the substrate to reactant precursor from the same injection module.

18. The method of claim 12, wherein the injecting of both the reactant precursor and the source precursor onto a surface of the substrate is according to an atomic layer deposition method.
